(19) United States
(12) Patent Application Publication
(10) Pub. No.: US 2026/0096167 A1
(43) Pub. Date: Apr. 2, 2026

(54) NITRIDE SEMICONDUCTOR DEVICE

(71) Applicant: Xiamen San’an Integrated Circuit Co., Ltd., Xiamen (CN)

(72) Inventors: Jiebin Zhong, Xiamen (CN); Boting LIU, Xiamen City (CN); Shenghou LIU, Xiamen (CN); Xiguo SUN, Xiamen (CN)

(21) Appl. No.: 19/196,484

(22) Filed: May 1, 2025

(30) Foreign Application Priority Data
Sep. 30, 2024 (CN) 202411383284.7

(51) Int. Cl. H10D 62/824; H10D 30/47; H10D 62/85

(52) U.S. Cl. CPC H10D 62/824; H10D 62/8503; H10D 30/475

(57) ABSTRACT

The nitride semiconductor device includes a first nitride layer including a binary nitride compound, a second nitride layer disposed on the first nitride layer and including a first element, a second element, and a third element, and a third nitride layer disposed on the second nitride layer and including the first element. A band gap of the third nitride layer is greater than that of the second nitride layer. A two-dimensional electron gas is generated in the first nitride layer. A maximum concentration value of the first element of the second nitride layer is no greater than a concentration value of the first element of the third nitride layer. Along a thickness direction, thicknesses the first nitride layer, the second nitride layer, and the third nitride layer is represented by d1, d2, and d3, respectively, where d2<d1, and 5 Å≤d2≤60 Å.

### CROSS-REFERENCE TO RELATED APPLICATION

This application claims priority to Chinese Invention Patent Application No. 202411383284.7, filed on Sep. 30, 2024, the entire disclosure of which is incorporated by reference herein.

### FIELD

The disclosure relates to a nitride semiconductor device, and more particularly to a semiconductor device used in the radio frequency (RF) field.

### BACKGROUND

By virtue of piezoelectric polarization, a two-dimensional electron gas (2DEG) having high mobility and high density is generated at an AlGaN/GaN heterojunction interface of a GaN-based high electron mobility transistor (GaN HEMT), thereby allowing the GaN-based HEMT to perform high-frequency signal processing and transmission under high power.

JP2004200711A discloses a technique for improving electrical performance of a GaN radio frequency (RF) device by disposing an AlN layer between an electron transmission layer and an electron supply layer. The AlN layer has a thickness that ranges from one molecular layer to four molecular layers. In one embodiment, the thickness of the AlN layer ranges from 2 molecular layers to 5 angstroms, and the AlN layer has a band gap of 6.2 eV, which may reduce current injection from a channel layer to a barrier layer, and the AlN layer may serve as a heterojunction. In addition, for a GaN RF device, the AlN layer may not be too thick. Generally, the thickness of the AlN layer ranges from 0.2 nm to 2 nm; otherwise, gate leakage current might occur and drain leakage current may be too high, thereby causing failure of the GaN RF device. On the other hand, an AlN layer having a thickness that is too small is unable to increase current density.

Therefore, increasing carrier concentration and reducing defect scattering while improving the current density and reliability of the GaN-based HEMT is a technical issue to be resolved.

### SUMMARY

Therefore, an object of the disclosure is to provide a nitride semiconductor device that can alleviate at least one of the drawbacks of the prior art.

According to the disclosure, the nitride semiconductor device includes a first nitride layer, a second nitride layer, and a third nitride layer.

The first nitride layer includes a binary nitride compound.

The second nitride layer is disposed on the first nitride layer. The first nitride layer has a first surface and a second surface that are opposite to each other. The second surface is at an interface of the first nitride layer and the second nitride layer. A thickness direction is defined from the first surface to the second surface. The second nitride layer includes a first element, a second element, and a third element. The first element is an aluminum element, the second element is a nitrogen element, and the third element is a gallium element. A concentration of the first element increases along the thickness direction.

The third nitride layer is disposed on the second nitride layer. The third nitride layer is a layer of ternary nitrogen compound or a quaternary nitrogen compound, and the third nitride layer includes the first element.

A band gap of the third nitride layer is greater than a band gap of the second nitride layer. A two-dimensional electron gas is generated in the first nitride layer.

A maximum concentration value of the first element of the second nitride layer is no greater than a concentration value of the first element of the third nitride layer.

Along the thickness direction, a thickness the first nitride layer is represented by d1, a thickness of the second nitride layer is represented by d2, and a thickness of the third nitride layer is represented by d3, where d2<d1, and 5Å≤d2≤60 Å.

A radio frequency (RF) amplifier including the nitride semiconductor device and a communication device including the RF amplifier are also disclosed.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view of a first embodiment of a nitride semiconductor device according to the disclosure.

FIG. 2 is a schematic view of the first embodiment of the nitride semiconductor device including a nucleation layer according to the disclosure.

FIG. 3 is a schematic view of the first embodiment of the nitride semiconductor device including the nucleation layer and a cap layer according to the disclosure.

FIG. 4 are graphs of the first embodiment and a comparative example each illustrating a relationship between Vds and Ids at Vgs=2V.

FIG. 5 are graphs of the first embodiment and the comparative example each illustrating a result of a high temperature reverse bias (HTRB) test.

FIG. 6 is a schematic view of a second embodiment of the nitride semiconductor device according to the disclosure.

FIG. 7 is a schematic view of the second embodiment of the nitride semiconductor device including the nucleation layer according to the disclosure.

FIG. 8 is a schematic view of the second embodiment of the nitride semiconductor device including the nucleation layer and the cap layer according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Furthermore, the terms “first,” “second,” and other ordinal numbers used in connection with technical features are solely for descriptive purposes, and should not be understood as indicating or implying relative importance of the technical features or implying the quantity of the technical features.

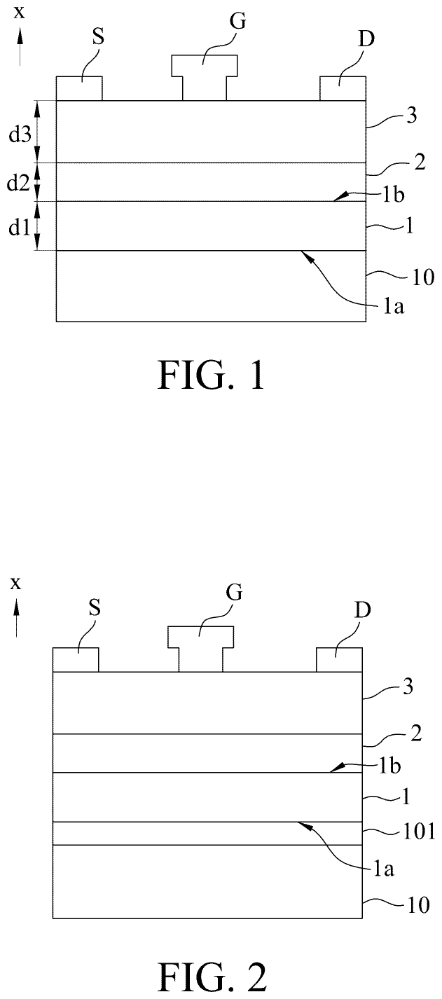

Referring to FIG. 1, a first embodiment of a nitride semiconductor device according to the disclosure is provided, and includes a source electrode (S), a drain electrode (D), and a gate electrode (G). The source electrode (S) and the drain electrode (D) are disposed opposite to each other on an epitaxial structure of the nitride semiconductor device, and the gate electrode (G) is disposed between the source electrode (S) and the drain electrode (D), and on the epitaxial structure. The epitaxial structure includes a first nitride layer 1 disposed on a substrate 10, a second nitride layer 2 disposed on the first nitride layer 1, and a third nitride layer 3 disposed on the second nitride layer 2. The first nitride layer 1 includes a binary nitride compound, and has a first surface 1a and a second surface 1b that are opposite to each other. The second surface 1b is at an interface of the first nitride layer 1 and the second nitride layer 2. A thickness direction (x) is defined from the first surface 1a to the second surface 1b. The second nitride layer 2 includes a first element, a second element, and a third element. The first element is an aluminum element, the second element is a nitrogen element, and the third element is a gallium element. A concentration of the first element increases along the thickness direction (x). The third nitride layer 3 is a layer of ternary nitrogen compound or a quaternary nitrogen compound, and includes the first element.

A band gap of the third nitride layer 3 is greater than a band gap of the second nitride layer 2, and a two-dimensional electron gas is generated in the first nitride layer 1. A maximum concentration value of the first element of the second nitride layer 2 is no greater than a concentration value of the first element of the third nitride layer 3. Along the thickness direction (x), a thickness of the first nitride layer is represented by d1, a thickness of the second nitride layer is represented by d2, and a thickness of the third nitride layer is represented by d3, where d2<d1, and 5 Å≤d2≤60 Å.

In this embodiment, the first nitride layer 1 is an undoped layer or an unintentionally doped GaN layer, and 1000 Å≤d1≤5000 Å.

In other embodiments, 10 Å≤d2≤40 Å. When d2 is smaller than 10 Å, a greater barrier is formed at the interface of the second nitride layer 2 and the first nitride layer 1. The barrier has a quantum confinement effect on electrons of a channel layer and may mitigate electron leakage of an AlGaN/GaN HEMT device. As the thickness (d2) of the second nitride layer 2 increases, the quantum confinement effect becomes better, density of two dimensional electron gas area becomes greater, and current density of the nitride semiconductor device becomes greater. However, the thickness (d2) of the second nitride layer 2 may not be too large. When d2 is greater than 40 Å, manufacturing of the nitride semiconductor device (e.g., ohmic processing) may be difficult. For example, source ohmic contact and drain ohmic contact may be difficult to form, thereby harder to form a good ohmic contact. In addition, when the thickness (d2) of the second nitride layer 2 is too large, lattice mismatch may easily occur at the interface of the second nitride layer 2 and the first nitride layer 1, which produces more growth defects, thereby causing mobility of the two-dimensional electron gas to decrease, an overall current to decrease, and radio frequency (RF) performance to decrease.

The substrate 10 may be made of silicon carbide (SiC), sapphire, silicon, etc. In this embodiment, the substrate 10 is a SiC substrate.

The third nitride layer 3 has a composition that is represented by Al_{y}Ga_{1-y}N, and 15%≤y≤35%. A sum of the thickness (d1) of the first nitride layer 1 and the thickness (d2) of the second nitride layer 2 is represented by d1+d2, and 1005 Å≤d1+d2≤5060 Å. Specifically, the second nitride layer 2 has a composition that is represented by AlₓGa₁₋ₓN. From the interface (i.e., the second surface 1b) between the first nitride layer 1 and the second nitride layer to an interface between the second nitride layer 2 and the third nitride layer 3, a value of x gradually increases from 0 to y.

In this embodiment, a ratio of the thickness (d1) of the first nitride layer 1 to the thickness (d2) of the second nitride layer 2 is represented by d1/d2, and 17≤d1/d2≤1000.

When d1/d2 is smaller than 17, that is to say, the thickness (d1) of the first nitride layer 1 is too small, or the thickness (d2) of the second nitride layer 2 is too large. And when the third nitride layer 3 (an Al_{y}Ga_{1-y}N barrier layer; y being a fixed value) is disposed on the second nitride layer 2, the second nitride layer 2 and/or the third nitride layer 3 may produce epitaxial defects, thereby causing excessive leakage and poor reliability. When the thickness (d1) of the first nitride layer 1 is too small, particularly when the thickness (d1) of the first nitride layer 1 is smaller than 1000 Å, crystal quality of the first nitride layer 1 is poorer, thereby causing defect-induced electron scattering between the first nitride layer 1 and the second nitride layer 2, which decreases the current density. At the same time, due to the decrease in lattice quality, the epitaxial defects may further cause problems such as current collapse.

When the ratio (d1/d2) of the thickness (d1) of the first nitride layer 1 to the thickness (d2) of the second nitride layer 2 is greater than 1000, the thickness (d1) of the first nitride layer 1 is too large, or the thickness (d2) of the second nitride layer 2 is too small. In that case, the current density of the nitride semiconductor device may not be improved. Like a conventional epitaxial structure where an AlN layer is disposed between the barrier layer and the channel layer, when this embodiment has a transition insertion layer and a more effective barrier, the current density is relatively small.

In some embodiments, 35≤d1/d2≤350. In this range, the nitride semiconductor device has even better current density.

In other embodiments, referring to FIG. 2, the nitride semiconductor device further includes a nucleation layer 101 disposed between the substrate 10 and the first nitride layer 1. The nucleation layer 101 is made of AlN or AlGaN, and has a thickness that ranges from 100 Å to 3000 Å. The nucleation layer 101 disposed on the substrate 10 forms a high quality surface for epitaxial growth and provides a good foundation for the subsequent epitaxial growth, thereby significantly decreasing dislocation density of materials, improving lattice quality, and improving characteristics such as electron mobility, breakdown voltage, and leakage current of the nitride semiconductor device.

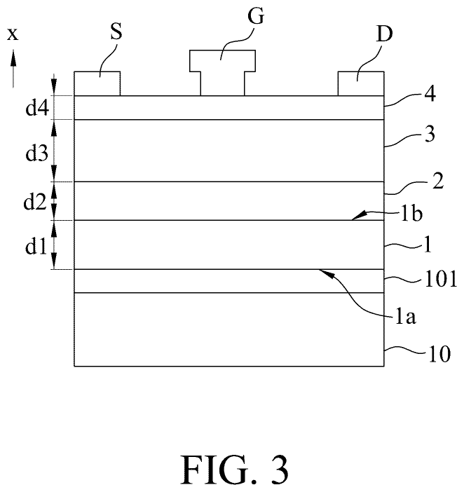

The nitride semiconductor device further includes a cap layer 4 that is an unintentionally doped GaN layer. Referring to FIG. 3, it should be noted that the cap layer 4 may prevent the third nitride layer 3 from oxidation and reduction in performance of the nitride semiconductor device. The cap layer 4 may also reduce surface defects and improve the performance of the nitride semiconductor device. A thickness of the cap layer 4 is represented by d4 along the thickness direction (x). A sum of the thickness (d2) of the second nitride layer 2, the thickness (d3) of the third nitride layer 3, and the thickness (d4) of the cap layer 4 is represented by d2+d3+d4, and 110 Å≤(d2+d3+d4)≤460 Å.

A ratio of the thickness (d3) of the third nitride layer 3 to the thickness (d2) of the second nitride layer 2 is represented by d3/d2, and 2≤d3/d2≤70.

When d3/d2 is smaller than 2, that is to say, the thickness (d3) of the third nitride layer 3 is too small, or the thickness (d2) of the second nitride layer 2 is too large (an insertion layer is too thick), a direct tunneling effect and the Fowler-Nordheim tunneling may occur. Due to the thickness (d3) of the third nitride layer 3 being small, growth of the third nitride layer 3 is not complete and is prone to lattice defects, thereby leading to defect-induced tunneling effects (e.g., Trap-Assisted Tunneling), which may lead to excessive leakage currents at the gate electrode (G), an increased risk of leakage, and adverse impact on the reliability of the nitride semiconductor device.

When d3/d2 is greater than 70, that is to say, the thickness (d2) of the second nitride layer 2 is too small, an effective increase of conduction band (ΔEc) caused by a structural polarization effect is not significant, a deeper quantum well is not produced, and a higher electron concentration is not produced due to a lack of increase in electron density and electron mobility, which leads to a smaller carrier concentration, a smaller transconductance and a lower RF performance, such as a lower gain performance and a lower power density. On the other hand, when the gate electrode (G) is too far away from the two-dimensional electron gas, gate control capability is limited, the source-drain current (I_{DS}) leakage becomes poorer during high-voltage applications, and the reliability of the nitride semiconductor device is reduced.

In some embodiments, 5≤d3/d2≤20.

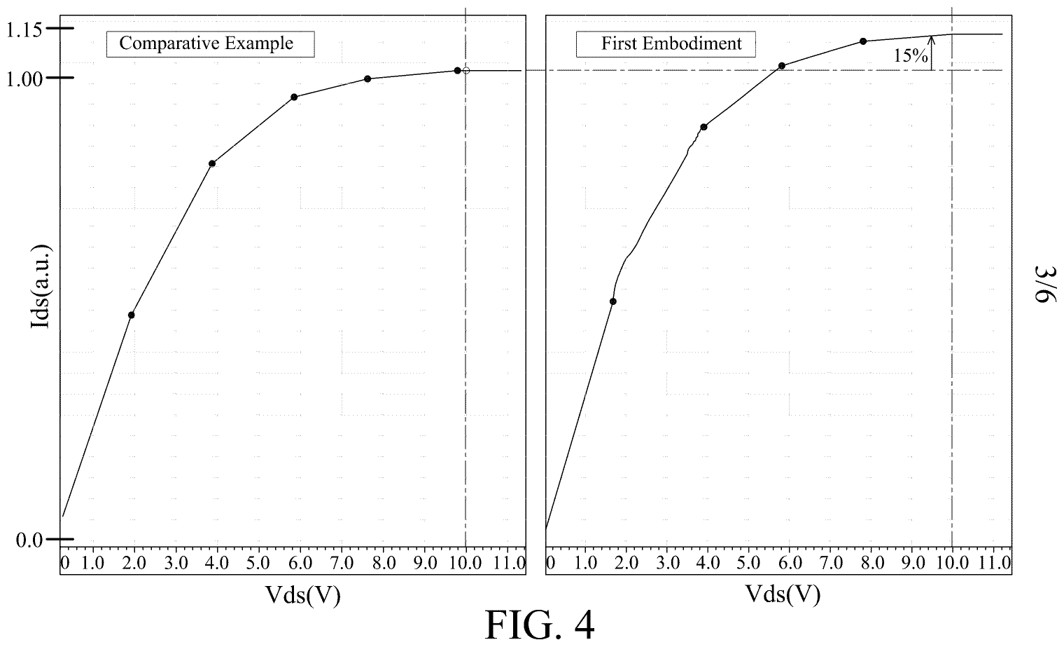

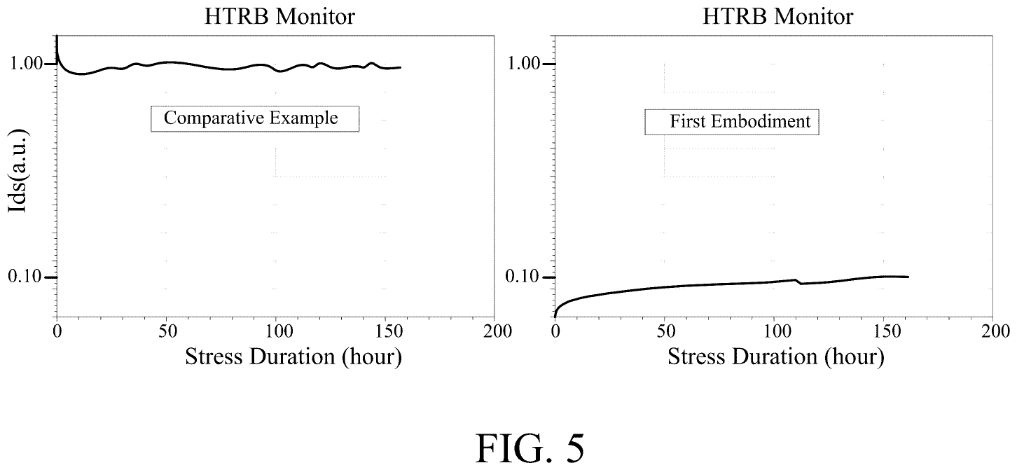

In one example of the first embodiment, the nitride semiconductor device includes the nucleation layer 101 that is made of AlN, the first nitride layer 1, the second nitride layer 2, and the third nitride layer 3 sequentially formed on the substrate 10 that is made of SiC. The substrate 10 has a thickness of 500 μm, and the nucleation layer 101 has a thickness of 200 Å. The first nitride layer 1 is an unintentionally doped GaN layer and has a thickness (d1) of 3000 Å, and the thickness (d2) of the second nitride layer 2 is 20 Å. The composition of the second nitride layer 2 is represented by AlₓGa₁₋ₓN. From the interface (i.e., the second surface 1b) between the first nitride layer 1 and the second nitride layer 2 to the interface between the second nitride layer 2 and the third nitride layer 3, the value of x gradually increases from 0 to 0.2. The composition of the third nitride layer 3 is represented by Al_{0.2}Ga_{0.8}N, and the thickness (d3) of the third nitride layer 3 is 200 Å. An Ids vs. Vds curve at Vgs=2V for this example of the first embodiment is shown in FIG. 4 (see the right side curve). The results of high temperature reverse bias (HTRB) test for this example of the first embodiment are shown in FIG. 5 (see the right side curve).

### Comparative Example

A comparative example of the nitride semiconductor device for comparison with the above example of the first embodiment includes an AlN nucleation layer, an unintentionally doped GaN layer, an AlN insertion layer, and a barrier layer sequentially disposed on a SiC substrate. The SiC substrate has a thickness of 500 μm, the AlN nucleation layer has a thickness of 200 Å, the unintentionally doped GaN layer has a thickness of 3000 Å, and the AlN insertion layer has a thickness of 20 Å. The barrier layer has a composition that is represented by Al_{0.2}Ga_{0.8}N, and a thickness of 200 Å. An Ids vs. Vds curve at Vgs=2V for the comparative example is shown in FIG. 4 (see the left side curve). The results of high temperature reverse bias (HTRB) test for the comparative example is shown in FIG. 5 (see the left side curve). In FIG. 4, the horizontal axis represents drain source voltage (Vds), and the unit of Vds is volt; the vertical axis represents Ids (a.u.), which denotes relative strength of the drain source current. In FIG. 5, the horizontal axis represents the stress duration in hours, and the vertical axis represents the relative strength of the drain source current; a.u is an abbreviation for arbitrary unit, which refers to any unit and indicates the relative strength in this case.

Referring to FIG. 4, comparing the example of the first embodiment with the comparative example, the drain source current of the first embodiment is 15% higher than that of the comparative example. Referring to FIG. 5, the first embodiment may lower the drain source current thereof to a tenth of that of the comparative example, thereby improving the reliability of the nitride semiconductor device.

Accordingly, the nitride semiconductor device of this embodiment may be implemented in an RF amplifier. The RF amplifier may be used in communication equipment such as microwave systems, radar, wireless communication modules, network equipment, and the like.

Accordingly, the nitride semiconductor of this embodiment may also be implemented in a communication device including the RF amplifier. The communication equipment may be a microwave system, a radar, a wireless communication module, a network device, and the like.

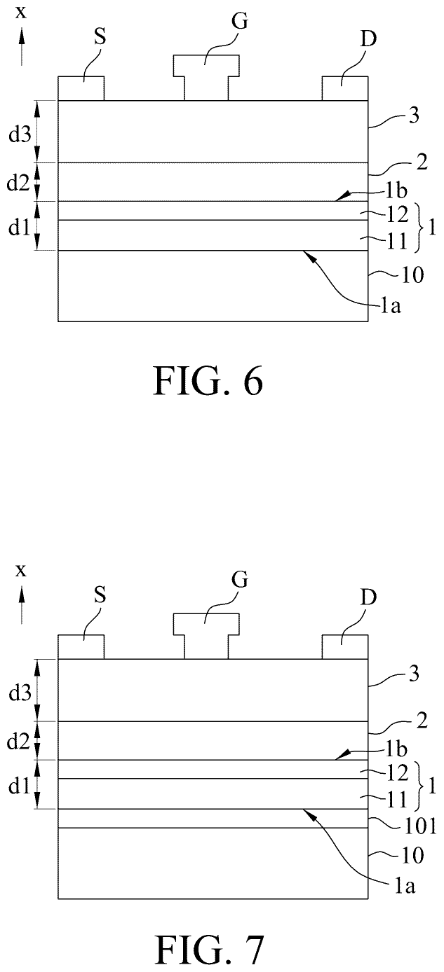

Referring to FIG. 6, a second embodiment of the nitride semiconductor device has a structure similar to that of the first embodiment except that in the first embodiment of the nitride semiconductor device, the first nitride layer 1 is an unintentionally doped GaN layer, whereas in the second embodiment, the first nitride layer 1 includes a first GaN layer 11 and a second GaN layer 12 disposed on the first GaN layer 11. The second GaN layer 12 is an unintentionally doped GaN layer and has a thickness that ranges from 1000 Å to 5000 Å. The first GaN layer 11 is doped with either C or Fe, and 2000 Å≤d1≤20000 Å. The sum of the thickness (d1) of the first nitride layer 1 and the thickness (d2) of the second nitride layer 2 is represented by d1+d2, and 3005 Å≤d1+d2≤25060 Å.

In some embodiments, 50≤d1/d2≤5000. By virtue of a greater thickness of the first nitride layer 1, the electron density and the electron mobility may be improved, thereby increasing the electron concentration, reducing current leakage, and improving the reliability of the nitride semiconductor device.

In other embodiments, 100≤d1/d2 ≤3000. In this range, the nitride semiconductor device may have more improved performance on current concentration, current collapse, and reliability.

Furthermore, in this embodiment, referring to FIG. 7, the nitride semiconductor device further includes the nucleation layer 101 disposed between the substrate 10 and the first nitride layer 1. The nucleation layer 101 is made of AlN or AlGaN, and has a thickness that ranges from 100 Å to 3000 Å. The nucleation layer 101 disposed on the substrate 10 forms a high quality surface for epitaxial growth and provides a good foundation for the subsequent epitaxial growth, thereby significantly decreasing the dislocation density of materials, improving the lattice quality, and improving the characteristics such as electron mobility, breakdown voltage, and leakage current of the nitride semiconductor device.

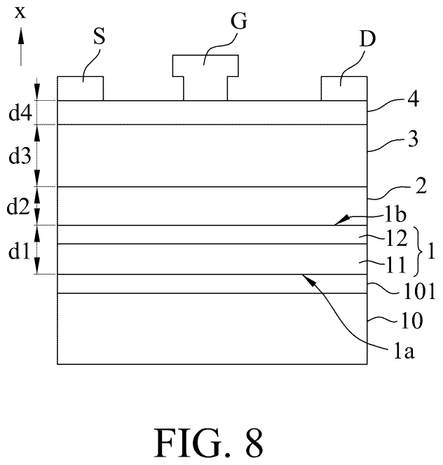

In this embodiment, the nitride semiconductor device further includes the cap layer 4 that is an unintentionally doped GaN layer. Referring to FIG. 8, it should be noted that the cap layer 4 may prevent the third nitride layer 3 from oxidation and reduction in the performance of the nitride semiconductor device. The cap layer 4 may also reduce the surface defects and improve the performance of the nitride semiconductor device. The thickness of the cap layer 4 is represented by d4 along the thickness direction (x). The sum of the thickness (d2) of the second nitride layer 2, the thickness (d3) of the third nitride layer 3, and the thickness (d4) of the cap layer 4 is represented by d2+d3+d4, and 110Å≤(d2+d3+d4)≤460 Å.

Accordingly, the nitride semiconductor device of this embodiment may be implemented in an RF amplifier. The RF amplifier may be used in communication equipment such as microwave systems, radar, wireless communication modules, network equipment, and the like.

Accordingly, the nitride semiconductor device of this embodiment may be implemented in a communication device including the RF amplifier. The communication equipment may be a microwave system, a radar, a wireless communication module, a network device, and the like.

In other embodiments, the third nitride semiconductor layer 3 has a composition that is represented by In_{1-z}Al_{z}N or InₖAlⱼGa₁₋ⱼ₋ₖN. When the composition of the third nitride semiconductor layer 3 is represented by In_{1-z}Al_{z}N, 70≤z≤100%. When the composition of the third nitride semiconductor layer 3 is represented by InₖAlⱼGa₁₋ⱼ₋ₖN, 0<k≤20% and 10%≤j<80%.

It should be noted that, in actual applications, the thickness of the substrate 10 of the nitride semiconductor device may further be reduced by a thinning process. For example, the thickness of the substrate 10 that is made of SiC is 500 μm, and after the thinning process, the thickness thereof may be reduced to 100 μm.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A nitride semiconductor device, comprising:
a first nitride layer, said first nitride layer including a binary nitride compound;
a second nitride layer disposed on the first nitride layer, said first nitride layer having a first surface and a second surface that are opposite to each other, said second surface being at an interface of said first nitride layer and said second nitride layer, a thickness direction being defined from said first surface to said second surface, said second nitride layer including a first element, a second element, and a third element, said first element being an aluminum element, said second element being a nitrogen element, said third element being a gallium element, a concentration of said first element increasing along the thickness direction; and
a third nitride layer disposed on said second nitride layer, said third nitride layer being a layer of ternary nitrogen compound or a quaternary nitrogen compound, said third nitride layer including said first element;
a band gap of said third nitride layer being greater than a band gap of said second nitride layer, a two-dimensional electron gas being generated in said first nitride layer;
a maximum concentration value of said first element of said second nitride layer being no greater than a concentration value of said first element of said third nitride layer;
along the thickness direction, a thickness said first nitride layer being represented by d1, a thickness of said second nitride layer being represented by d2, a thickness of said third nitride layer being represented by d3;
wherein d2<d1, and 5 Å≤d2≤60 Å.

2. The nitride semiconductor device as claimed in claim 1, further comprising a substrate, and a nucleation layer disposed between said substrate and said first nitride layer.

3. The nitride semiconductor device as claimed in claim 1, further comprising a cap layer.

4. The nitride semiconductor device as claimed in claim 3, wherein said cap layer is an unintentionally doped GaN layer.

5. The nitride semiconductor device as claimed in claim 3, wherein a thickness of said cap layer is represented by d4 along the thickness direction, a sum of said thickness of said second nitride layer, said thickness of said third nitride layer, and said thickness of said cap layer being represented by d2+d3+d4, 110Å≤(d2+d3+d4)≤460 Å.

6. The nitride semiconductor device as claimed in claim 1, wherein said first nitride layer is an unintentionally doped GaN layer, and 1000 Å≤d1≤5000 Å.

7. The nitride semiconductor device as claimed in claim 6, wherein a sum of said thickness of said first nitride layer and said thickness of said second nitride layer is represented by d1+d2, and 1005 Å≤d1+d2≤5060 Å.

8. The nitride semiconductor device as claimed in claim 6, wherein a ratio of said thickness of said first nitride layer to said thickness of said second nitride layer is represented by d1/d2, and 17≤d1/d2≤1000.

9. The nitride semiconductor device as claimed in claim 8, wherein 35≤d1/d2≤350.

10. The nitride semiconductor device as claimed in claim 1, wherein said third nitride layer has a composition that is represented by one of Al_{y}Ga_{1-y}N, In_{1-z}Al_{z}N and InₖAlⱼGa₁₋ⱼ₋ₖN, 15%≤y≤35%, 70≤z≤100%, 0<k≤20%, 10%≤j<80%.

11. The nitride semiconductor device as claimed in claim 1, wherein said first nitride layer includes a first GaN layer and a second GaN layer that is disposed on said first GaN layer, said second GaN layer being an unintentionally doped GaN layer, said first GaN layer being doped with either C or Fe.

12. The nitride semiconductor device as claimed in claim 11, wherein said second GaN layer has a thickness that ranges from 1000 Å to 5000 Å.

13. The nitride semiconductor device as claimed in claim 11, wherein 2000 Å≤d1≤20000 Å.

14. The nitride semiconductor device as claimed in claim 11, wherein a sum of said thickness of said first nitride layer and said thickness of said second nitride layer is represented by d1+d2, and 3005 Å≤d1+d2≤25060 Å.

15. The nitride semiconductor device as claimed in claim 11, wherein 50≤d1/d2≤5000.

16. The nitride semiconductor device as claimed in claim 15, wherein 100≤d1/d2≤3000.

17. The nitride semiconductor device as claimed in claim 1, wherein a ratio of said thickness of said third nitride layer to said thickness of said second nitride layer is represented by d3/d2, and 2≤d3/d2≤70.

18. The nitride semiconductor device as claimed in claim 17, wherein 5≤d3/d2≤20.

19. A radio frequency (RF) amplifier, comprising the nitride semiconductor device as claimed in claim 1.

20. A communication device, comprising the RF amplifier as claimed in claim 19.
